(19) United States
(12) Patent Application Publication
(10) Pub. No.: US 2021/0211146 A1
(43) Pub. Date: Jul. 8, 2021

(54) FRONT END MODULE

(71) Applicant: Samsung Electro-Mechanics Co., Ltd., Suwon-si (KR)

(72) Inventors: Tah Joon PARK, Suwon-si (KR); Sung Tae KIM, Suwon-si (KR); Chan Hee PARK, Suwon-si (KR); Won Kyu JEUNG, Suwon-si (KR)

(73) Assignee: Samsung Electro-Mechanics Co., Ltd., Suwon-si (KR)

(21) Appl. No.: 16/874,909

(22) Filed: May 15, 2020

(30) Foreign Application Priority Data
Jan. 7, 2020 (KR) 10-2020-0001872

(51) Int. Cl. H04B 1/04; H01Q 21/28; H03H 9/70; H04B 1/00

(52) U.S. Cl. CPC H04B 1/04; H04B 1/0057; H03H 9/706; H01Q 21/28

(57) ABSTRACT

A front end module includes an antenna terminal connected to an antenna, a first filter having a first end connected to the antenna terminal and having a first pass band; and a second filter having a first end connected to the antenna terminal and having a second pass band different from the first pass band. The first filter and the second filter simultaneously filter an RF signal received by the antenna, and simultaneously filter an RF signal transmitted externally through the antenna. The first filter and the second filter are configured to support wireless communications of a same standard.

### CROSS-REFERENCE TO RELATED APPLICATION(S)

This application claims benefit under 35 USC 119(a) of Korean Patent Application No. 10-2020-0001872 filed on Jan. 7, 2020 in the Korean Intellectual Property Office, the entire disclosure of which is incorporated herein by reference for all purposes.

### BACKGROUND

### 1. Field

The following description relates to a front end module.

### 2. Description of Background

5th generation (5G) communications are expected to connect relatively more devices more efficiently with more large-capacity data and at faster data transmission speeds, compared with existing Long Term Evolution (LTE) communications.

5th generation communications are developing in the direction of using the frequency band of 24250 MHz to 52600 MHz, corresponding to the millimeter wave (mmWave) band, and the 450 MHz to 6000 MHz frequency band, corresponding to the sub-6 GHz band.

Each of an n77 band (3300 MHz to 4200 MHz), an n78 band (3300 MHz to 3800 MHz) and an n79 band (4400 MH to 5000 MHz) was defined as one of the operating bands of sub-6 GHz, and an n77 band (3300 MHz to 4200 MHz), an n78 band (3300 MHz to 3800 MHz) and an n79 band (4400 MH to 5000 MHz) are expected to be used as main bands through the advantage of having a wide bandwidth.

In the n79 band (4400 MH to 5000 MHz), since the band gap with existing 5 GHz Wi-Fi band (5150 MHz to 5950 MHz) is extremely narrow, it is necessary to apply a bulk acoustic wave (BAW) filter having excellent attenuation characteristics to prevent radio frequency (RF) signal interference. However, in the case of the BAW filter having excellent attenuation characteristics, since the passband is narrow, it is difficult to implement wideband characteristics.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

A front end module in which one communication band is divided into two bands and different filters are applied to the two bands.

In one general aspect, a front end module includes an antenna terminal connected to an antenna, a first filter having a first end connected to the antenna terminal and having a first pass band; and a second filter having a first end connected to the antenna terminal and having a second pass band different from the first pass band. The first filter and the second filter simultaneously filter an RF signal received by the antenna, and simultaneously filter an RF signal transmitted externally through the antenna. The first filter and the second filter are configured to support wireless communications of a same standard.

The first pass band and the second pass band may be separated from each other.

The first pass band may correspond to a band of 5.15 GHz to 5.35 GHz, and the second pass band may correspond to a band of 5.47 GHz to 5.85 GHz.

The first filter and the second filter may be configured to support one of Wi-Fi wireless communications and cellular wireless communications.

Each of the first filter and the second filter may include a bulk acoustic wave (BAW) filter.

The front end module may include a switch including a first terminal connected to a second end of the first filter and a second end of the second filter, and a second terminal and a third terminal selectively connected to the first terminal.

The front end module may include an RF integrated circuit (IC) including a transmission terminal connected to the second terminal and a receiving terminal connected to the third terminal.

The front end module of may include a power amplifier disposed between the second terminal and the transmission terminal.

The front end module may include a low noise amplifier disposed between the third terminal and the receiving terminal.

In another general aspect, a front end module includes an antenna terminal; a first filter disposed between the antenna terminal and a first terminal and having a first pass band; a second filter connected to the first filter in parallel and having a second pass band different from the first pass band; a switch including the first terminal and a second terminal and a third terminal selectively connected to the first terminal; and a radio frequency integrated circuit (RF IC) including a transmission terminal connected to the second terminal and a receiving terminal connected to the third terminal. The first filter and the second filter are configured to support wireless communications of a same standard.

Other features and aspects will be apparent from the following detailed description, the drawings, and the claims.

### BRIEF DESCRIPTION OF DRAWINGS

FIG. 1 is a block diagram of a mobile device equipped with a front end module according to an example.

FIG. 2 is a block diagram of a front end module according to a first example.

FIG. 3 is a block diagram of a front end module according to a second example.

FIG. 4 is a block diagram of a front end module according to a third example.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that would be well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will fully convey the scope of the disclosure to one of ordinary skill in the art.

Herein, it is noted that use of the term “may” with respect to an example or embodiment, e.g., as to what an example or embodiment may include or implement, means that at least one example or embodiment exists in which such a feature is included or implemented while all examples and embodiments are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there may be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as illustrated in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes illustrated in the drawings may occur. Thus, the examples described herein are not limited to the specific shapes illustrated in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

The drawings may not be to scale, and the relative size, proportions, and depiction of elements in the drawings may be exaggerated for clarity, illustration, and convenience.

Subsequently, examples are described in further detail with reference to the accompanying drawings.

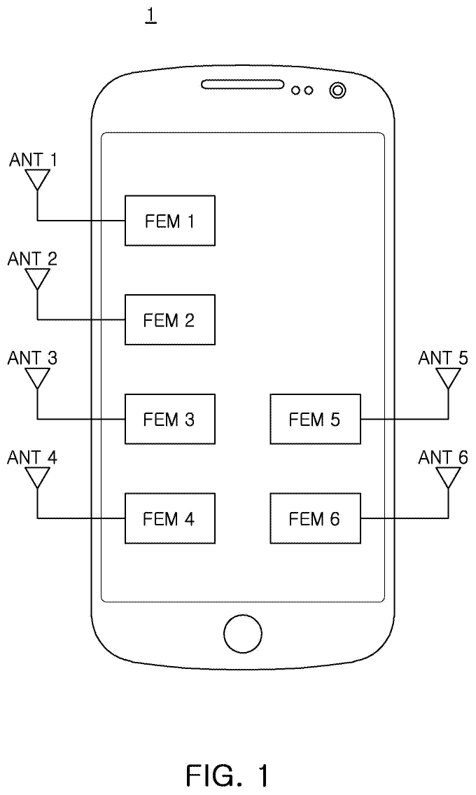

FIG. 1 is a block diagram of a mobile device equipped with a front end module according to an example.

Referring to FIG. 1, a mobile device 1 includes a plurality of antennas ANT1 , ANT2, ANT5, ANT4, ANT5, and ANT6, and a plurality of front end modules FEM1, FEM2, FEM3, FEM4, FEM5, and FEM6 connected to different antennas among the plurality of antennas ANT1 to ANT6.

The mobile device 1 performs wireless communications of various standards such as cellular (LTE/WCDMA/GSM) communication, Wi-Fi communications of 2.4 GHz and 5 GHz, and Bluetooth communication. The plurality of antennas ANT1 to ANT6 and the plurality of front end modules FEM1 to FEM6 included in the mobile device 1 support wireless communications of various standards.

However, when a plurality of antennas ANT1 to ANT6 are implemented in a limited space of the mobile device 1, RF signals transmitted and received from each of the plurality of antennas ANT1 to ANT6 interfere with each other, thereby deteriorating the performance of the antenna.

Therefore, it is necessary to reduce the number of antennas mounted on the mobile device 1 by supporting a plurality of standard wireless communications by a front end module connected to any one antenna.

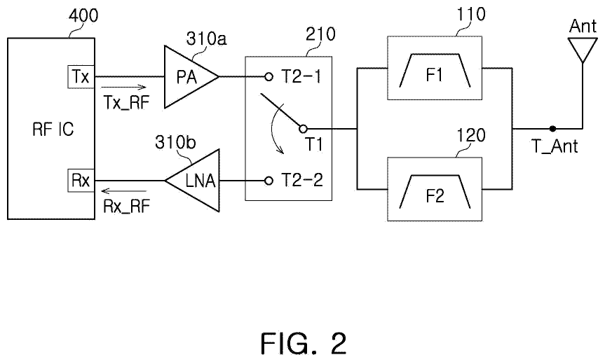

FIG. 2 is a block diagram of a front end module according to a first example.

The front end module includes a first filter 110, a second filter 120, a switch 210, a power amplifier (PA) 310a, a low noise amplifier (LNA) 310b, and an RF integrated circuit (RF IC) 400.

The first filter 110 has one end connected to an antenna terminal T_Ant and the other end connected to the switch 210, and is disposed between the antenna terminal T_Ant and the switch 210. The second filter 120 has one end connected to the antenna terminal T_Ant and the other end connected to the switch 210, and is disposed between the antenna terminal T_Ant and the switch 210. For example, the first filter 110 and the second filter 120 are connected between the antenna terminal T_Ant and the switch 210 in parallel. An antenna Ant configured to transmit and receive RF signals is connected to the antenna terminal T_Ant.

The first filter 110 includes a band pass filter having a pass band of a first frequency band. The first filter 110 filters the RF signal transmitted externally through the antenna Ant, and filters the RF signal received by the antenna Ant. The first filter 110 may be configured as a BAW filter. As an example, the first frequency band may correspond to 5.15 GHz to 5.35 GHz. The first frequency band may be allocated as a band for Wi-Fi communications, or the first frequency band may be allocated as a band for cellular communications.

The second filter 120 includes a band pass filter having a pass band of a second frequency band. The second filter 120 filters the RF signal transmitted externally through the antenna Ant, and filters the RF signal received by the antenna Ant. The second filter 120 may be configured as a BAW filter. For example, the second frequency band may correspond to 5.47 GHz to 5.85 GHz. The second frequency band may be allocated as a band for wireless communications of the same standard as the first frequency band. The second frequency band may be allocated as a band for Wi-Fi communications, or the second frequency band may be allocated as a band for cellular communications.

The first filter 110 and the second filter 120 have different pass bands. The pass band of the first filter 110 and the pass band of the second filter 120 are separated from each other, to stop from overlapping each other.

The switch 210 is implemented as a three-terminal switch in the form of a single pole double throw (SPDT). The switch 210 may include a first terminal T1, a second terminal T2-1, and a third terminal T2-2, where the second terminal T2-1 and the third terminal T2-2 are selectively connected to the first terminal T1.

The first terminal T1 of the switch 210 is connected to the other end of the first filter 110 and the other end of the second filter 120. The second terminal T2-1 of the switch 210 is connected to a transmission terminal Tx of the RF IC 400, and the third terminal T2-2 of the switch 210 is connected to a receiving terminal Rx of the RF IC 400.

The first filter 110 and the second filter 120 may be selectively connected to the transmitting terminal Tx and the receiving terminal Rx of the RF IC 400 through the switch 210.

The front end module may further include the power amplifier 310a and the low noise amplifier 310b. The power amplifier 310a is disposed in a transmission path Tx_RF of the RF signal between the second terminal T2-1 and the transmission terminal Tx, and amplifies the RF signal transmitted externally through the antenna Ant. The low-noise amplifier 310b is disposed in a reception path Rx_RF of the RF signal between the third terminal T2-2 and the receiving terminal Rx, and amplifies the RF signal received through the antenna Ant.

Although FIG. 2 illustrates that the power amplifier 310a is disposed in the transmission path Tx_RF and the low-noise amplifier 310b is disposed in the reception path Rx_RF, the power amplifier 310a may be removed from the transmission path Tx_RF, or the low-noise amplifier LNA may be removed from the reception path Rx_RF, depending on the need for amplification based on the design.

The RF IC 400 may control overall communication of the front end module. The RF IC 400 provides an RF signal through a transmission path Tx_RF, and receives an RF signal through a reception path Rx_RF.

For example, the RF IC 400 is connected to each of the power amplifier 310a and the low noise amplifier 310b, so that the RF IC 400 provides an RF signal to the power amplifier 310a disposed in the transmission path Tx_RF. The RF signal is provided from the low noise amplifier 310b disposed in the reception path Rx_RF.

Normally, the 5.15 GHz to 5.925 GHz band is allocated as the band for 5 GHz Wi-Fi communications. The BAW filter has excellent attenuation characteristics, but since it is difficult to form a wide passband, it is difficult to apply one BAW filter to the 5.15 GHz to 5.925 GHz band requiring broadband frequency characteristics.

On the other hand, among the 5.15 GHz to 5.925 GHz bands, the 5.35 GHz to 5.47 GHz bands correspond to unlicensed bands, and the 5.47 GHz to 5.85 GHz bands are bands allocated to amateur radio operators. Therefore, practically, the 5.15 GHz to 5.35 GHz bands and the 5.47 GHz to 5.85 GHz bands are used as the bands for Wi-Fi communications.

Accordingly, when a BAW filter having a pass band of 5.15 GHz to 5.35 GHz band and a BAW filter having a pass band of 5.47 GHz to 5.85 GHz band are applied to the 5.15 GHz to 5.35 GHz band and the 5.47 GHz to 5.85 GHz band, respectively, practically, reducing insertion loss of the entire 5.15 GHz to 5.925 GHz bands may be implemented.

According to this example, using the first filter 110 having a pass band of 5.15 GHz to 5.35 GHz band, and the second filter 120 having a pass band of 5.47 GHz to 5.85 GHz band, 5.15 GHz to 5.925, the insertion loss of the entire GHz band may be reduced.

According to this example, according to the switching operation of the switch 210, the transmission path Tx_RF and the reception path Rx_RF may be selectively connected to the first filter 110 and the second filter 120.

When the first terminal T1 of the switch 210 is connected to the second terminal T2-1, the first filter 110 and the second filter 120 are connected to the power amplifier 310a provided on the transmission path Tx_RF through the switch 210. Accordingly, a transmission path of the RF signal through the {RF IC 400—power amplifier 310a—switch 210—first filter 110/second filter 120—antenna Ant} is formed.

When the first terminal T1 of the switch 210 is connected to the third terminal T2-2, the first filter 110 and the second filter 120 are connected to the low-noise amplifier 310b provided on the reception path Rx_RF through the switch 210. Accordingly, a reception path of the RF signal through the {antenna Ant—first filter 110/second filter 120—switch 210—low noise amplifier 310b—RF IC 400} is formed.

According to this example, the first filter 110 and the second filter 120 are simultaneously connected to the transmission path Tx_RF, or simultaneously connected to the reception path Rx_RF, to significantly reduce the time delay in the time division scheme. As such, the number of power amplifiers 310a and low-noise amplifiers 310b connected to the first filter 110 and the second filter 120 is significantly reduced, thereby reducing manufacturing costs and reducing the product size.

In the above-described example, it has been described that two filters (the first filter 110 and the second filter 120) are disposed in parallel between the first terminal T1 and the antenna terminal T_Ant. According to the need for reduction in insertion loss, three or more filters may be disposed in parallel between the first terminal T1 and the antenna terminal T_Ant.

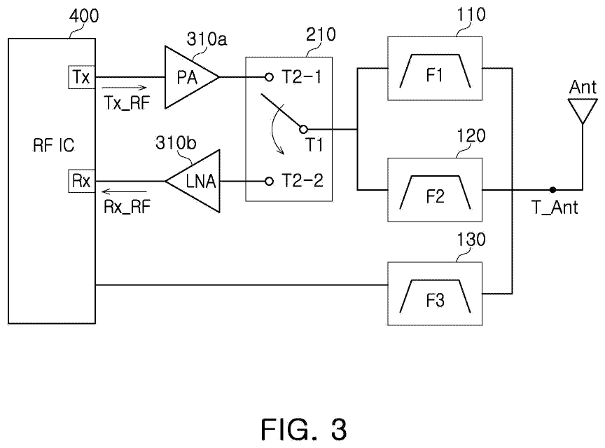

FIG. 3 is a block diagram of a front end module according to a second example.

Since the front-end module according to the second example has some similarity to the front-end module according to the first example, redundant description will be omitted, and the difference will be mainly described.

The front end module according to the second example may include a third filter 130. The third filter 130 is disposed between the antenna terminal T_Ant and an RF IC 400.

The third filter 130 includes a band pass filter having a pass band of a third frequency band. The third filter 130 may be configured as a BAW filter.

For example, the third frequency band may correspond to 3.3 GHz to 4.2 GHz, and the 3.3 GHz to 4.2 GHz bands may be allocated as bands for cellular communications. As another example, the third frequency band may correspond to 4.4 GHz to 5.0 GHz, and the 4.4 GHz to 5.0 GHz bands may be allocated as bands for cellular communications.

The third filter 130 filters the RF signal transmitted from the antenna Ant, provides the signal to the RF IC 400, or the third filter 130 filters the RF signal transmitted from the RF IC 400 and may transmit the signal to the antenna Ant.

A path between the third filter 130 and the RF IC 400 may be divided into two paths, so that one path may be used as a transmission path and one path as a reception path. The transmission path and the reception path may be selectively connected to the third filter 130 through a switch. Further, according to the need for signal amplification, a power amplifier may be disposed in the transmission path and a low noise amplifier may be disposed in the reception path.

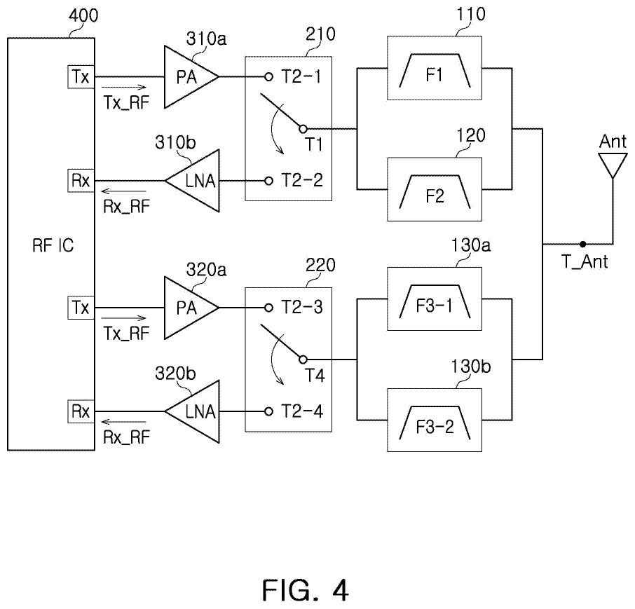

FIG. 4 is a block diagram of a front end module according to a third example.

Since the front end module according to the third example has some similarity to the front end module according to the first example, a duplicate description is omitted, and the difference will be mainly described.

The front end module according to the third example may include a third filter 130a, a fourth filter 130b, a switch 220, a power amplifier 320a, and a low-noise amplifier 320b.

The third filter 130a is disposed between the antenna terminal T_Ant and the switch 220, and the fourth filter 130b is disposed between the antenna terminal T_Ant and the switch 220. For example, the third filter 130a and the fourth filter 130b are connected between the antenna terminal T_Ant and the switch 220 in parallel.

The third filter 130a includes a band pass filter having a pass band of a third frequency band. The third filter 130a may be configured as a BAW filter. The fourth filter 130b includes a band pass filter having a pass band of a fourth frequency band. The fourth filter 130b may be configured as a BAW filter.

According to the need for reduced insertion loss, the third frequency band of the second example may be divided into two bands, and the third frequency band and the fourth frequency band of the third example may be determined. Therefore, the pass band of the third filter 130a and the pass band of the fourth filter 130b are separated from each other, to be prevented from overlapping each other.

The switch 220 is implemented as a three-terminal switch in the form of a single pole double throw (SPDT). The switch 220 may include a fourth terminal T4, and a fifth terminal T2-3 and a sixth terminal T2-4 selectively connected to the fourth terminal T4. The fourth terminal T4 of the switch 220 is connected to the third filter 130a and the fourth filter 130b. The fifth terminal T2-3 of the switch 220 is connected to the power amplifier 320a, and the sixth terminal T2-4 of the switch 220 is connected to the low noise amplifier 320b. The third filter 130a and the fourth filter 130b may be selectively connected to the power amplifier 320a and the low noise amplifier 320b through the switch 220.

The power amplifier 320a is disposed in the transmission path Tx_RF of the RF signal, and amplifies the RF signal transmitted externally through the antenna Ant. The low-noise amplifier 320b is disposed in the reception path Rx_RF of the RF signal to amplify the RF signal received through the antenna Ant.

Although FIG. 4 illustrates that the power amplifier 320a is disposed in the transmission path Tx_RF and the low-noise amplifier 320b is disposed in the reception path Rx_RF; depending on whether amplification is required according to design, the power amplifier 320a may be removed from the transmission path Tx_RF, or the low noise amplifier LNA may be removed from the reception path Rx_RF.

The RF IC 400 is connected to each of the power amplifier 320a and the low noise amplifier 320b, to provide an RF signal to the power amplifier 320a disposed in the transmission path Tx_RF and to receive an RF signal from the low-noise amplifier 320b disposed in the reception path Rx_RF.

Generally, the 3.3 GHz to 4.2 GHz or 4.4 GHz to 5.0 GHz band corresponding to the third frequency band is allocated as the band for cellular communications of Sub-6 GHz. The BAW filter has excellent attenuation characteristics, but since it is difficult to form a wide pass band, it is difficult to apply one BAW filter to the 3.3 GHz to 4.2 GHz or 4.4 GHz to 5.0 GHz band requiring broadband frequency characteristics.

According to an example, the third frequency band is divided into two bands, and the third filter 130a and the fourth filter 130b having a pass band of each of the two bands are used, thereby reducing insertion loss of the entire third frequency band.

When the fourth terminal T4 of the switch 220 is connected to the fifth terminal T2-3, the third filter 130a and the fourth filter 130b are connected to the power amplifier 320a provided in the transmission path Tx_RF through the switch 220. Thus, an RF signal transmission path through the {RF IC 400—power amplifier 320a—switch 220—third filter 130a/fourth filter 130b—antenna Ant} is formed.

When the fourth terminal T4 of the switch 220 is connected to the sixth terminal T2-4, the third filter 130a and the fourth filter 130b are connected to the low noise amplifier 320b provided in the reception path Rx_RF through the switch 220. Thus, an RF signal transmission path through the {antenna Ant—third filter 130a/fourth filter 130b—switch 220—low noise amplifier 320b—RF IC 400} is formed.

According to an example, the third filter 130a and the fourth filter 130b are simultaneously connected to the transmission path Tx_RF, or simultaneously connected to the reception path Rx_RF, thereby significantly reducing time delay in the time-division method. By significantly reducing the number of the power amplifier 320a and the low-noise amplifier 320b connected to the third filter 130a and the fourth filter 130b, manufacturing costs and the product size may be reduced.

In the above-described example, although two filters, for example, the third filter 130a and the fourth filter 130b are disposed in parallel between the fourth terminal T4 of the switch 220 and the antenna terminal T_Ant; according to the need for reducing insertion loss, three or more filters may be disposed in parallel between the fourth terminal T4 of the switch 220 and the antenna terminal T_Ant.

According to the various examples, various standards such as Wi-Fi communications and cellular communications are supported by one front module connected to one antenna, thereby reducing the number of antennas employed in the mobile device, whereby the isolation characteristics of the antenna may be improved.

As set forth above, according to various examples, one communication band is divided into two bands, and different filters are applied to the two bands, thereby reducing insertion loss of the entire communication band.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed to have a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A front end module comprising:
an antenna terminal connected to an antenna;
a first filter having a first end connected to the antenna terminal and having a first pass band; and
a second filter having a first end connected to the antenna terminal and having a second pass band different from the first pass band,
wherein the first filter and the second filter are configured to simultaneously filter a radio frequency (RF) signal received by the antenna, and to simultaneously filter an RF signal transmitted externally through the antenna, and
the first filter and the second filter are configured to support wireless communications of a same standard.

2. The front end module of claim 1, wherein the first pass band and the second pass band are separated from each other.

3. The front end module of claim 2, wherein the first pass band corresponds to a band of 5.15 GHz to 5.35 GHz, and the second pass band corresponds to a band of 5.47 GHz to 5.85 GHz.

4. The front end module of claim 1, wherein the first filter and the second filter are configured to support one of Wi-Fi wireless communications and cellular wireless communications.

5. The front end module of claim 1, wherein each of the first filter and the second filter comprises a bulk acoustic wave (BAW) filter.

6. The front end module of claim 1, further comprising a switch comprising a first terminal connected to a second end of the first filter and a second end of the second filter, and a second terminal and a third terminal selectively connected to the first terminal.

7. The front end module of claim 6, further comprising an RF integrated circuit (IC) comprising a transmission terminal connected to the second terminal and a receiving terminal connected to the third terminal.

8. The front end module of claim 7, further comprising a power amplifier disposed between the second terminal and the transmission terminal.

9. The front end module of claim 7, further comprising a low noise amplifier disposed between the third terminal and the receiving terminal.

10. A front end module comprising:
an antenna terminal;
a first filter disposed between the antenna terminal and a first terminal and having a first pass band;
a second filter connected to the first filter in parallel and having a second pass band different from the first pass band;
a switch including the first terminal and a second terminal and a third terminal selectively connected to the first terminal; and
a radio frequency integrated circuit (RF IC) comprising a transmission terminal connected to the second terminal and a receiving terminal connected to the third terminal,
wherein the first filter and the second filter are configured to support wireless communications of a same standard.

11. The front end module of claim 10, wherein the first pass band and the second pass band are separated from each other.

12. The front end module of claim 11, wherein the first pass band corresponds to a 5.15 GHz to 5.35 GHz band, and the second pass band corresponds to a 5.47 GHz to 5.85 GHz band.

13. The front end module of claim 10, wherein the first filter and the second filter are configured to support one of Wi-Fi wireless communications and cellular wireless communications.

14. The front end module of claim 10, wherein each of the first filter and the second filter comprises a bulk acoustic wave (BAW) filter.

15. The front end module of claim 10, further comprising a power amplifier disposed between the second terminal and the transmission terminal.

16. The front end module of claim 10, further comprising a low noise amplifier disposed between the third terminal and the receiving terminal.
